(19) United States
(12) Patent Application Publication
(10) Pub. No.: US 2024/0396524 A1
(43) Pub. Date: Nov. 28, 2024

(54) ACOUSTIC WAVE DEVICE

(71) Applicant: Murata Manufacturing Co., Ltd., Nagaokakyo-shi (JP)

(72) Inventor: Ryo NAKAGAWA, Nagaokakyo-shi (JP)

(21) Appl. No.: 18/598,311

(22) Filed: Mar. 7, 2024

(30) Foreign Application Priority Data
May 24, 2023 (JP) 2023-085142

(51) Int. Cl. H03H 9/25; H03H 9/02; H03H 9/145

(52) U.S. Cl. CPC H03H 9/25; H03H 9/02559; H03H 9/02637; H03H 9/02866; H03H 9/02937; H03H 9/145

(57) ABSTRACT

An acoustic wave device includes a piezoelectric substrate including a piezoelectric layer, and an IDT electrode on the piezoelectric layer and including first and second electrode fingers interdigitated with each other and coupled to mutually different potentials. A portion of the piezoelectric layer where the IDT electrode is provided includes an intersection region. When a direction in which the first electrode fingers and the second electrode fingers extend is an electrode finger extending direction, a direction orthogonal to the electrode finger extending direction is an electrode finger orthogonal direction, and the IDT electrode is viewed in the electrode finger orthogonal direction, a region where the first electrode finger and the second electrode finger, which are adjacent to each other, overlap each other is the intersection region. The piezoelectric layer includes a first region and a second region having a polarization direction different from that of the first region.

### CROSS REFERENCE TO RELATED APPLICATIONS

This application claims the benefit of priority to Japanese Patent Application No. 2023-085142 filed on May 24, 2023. The entire contents of this application are hereby incorporated herein by reference.

### BACKGROUND OF THE INVENTION

### 1. Field of the Invention

The present invention relates to an acoustic wave device.

### 2. Description of the Related Art

In the related art, acoustic wave devices are widely used as filters of mobile phones and the like. International Publication No. WO 2012/086639 discloses an example of an acoustic wave device. In the acoustic wave device, the support substrate, the high acoustic velocity film, the low acoustic velocity film, and the piezoelectric film are laminated in this order. An interdigital transducer (IDT) electrode is provided on the piezoelectric film. International Publication No. 2012/086639 discloses a mode having a P wave as a main component, a mode having a shear horizontal (SH) wave as a main component, and a mode having a shear vertical (SV) wave as a main component, as a main mode that propagates through the piezoelectric film.

### SUMMARY OF THE INVENTION

When the acoustic wave device is used as a high frequency filter, it is necessary that the frequency of the mode in which the acoustic wave device is operated is high. However, in the acoustic wave device of the related art, it is difficult to preferably excite a harmonic wave. For example, in the related art, the electromechanical coupling coefficient of the third harmonic wave is small, and the electromechanical coupling coefficient of the second harmonic wave is particularly small. In addition, when the second harmonic wave is used for the operation of the acoustic wave device, the fundamental wave becomes an unnecessary wave. Therefore, it is necessary to suppress the fundamental wave.

Example embodiments of the present invention provide acoustic wave devices that each excite a second harmonic wave and suppress a fundamental wave.

According to an example embodiment of the present invention, an acoustic wave device includes a piezoelectric substrate including a piezoelectric layer, and an IDT electrode provided on the piezoelectric layer and including a plurality of first electrode fingers and a plurality of second electrode fingers that are interdigitated with each other and coupled to mutually different potentials, in which a portion of the piezoelectric layer where the IDT electrode is provided includes an intersection region, and when a direction in which the plurality of first electrode fingers and the plurality of second electrode fingers extend is defined as an electrode finger extending direction, a direction orthogonal to the electrode finger extending direction is defined as an electrode finger orthogonal direction, and the IDT electrode is viewed in the electrode finger orthogonal direction, a region where the first electrode finger and the second electrode finger, which are adjacent to each other, overlap each other is the intersection region, the piezoelectric layer includes a first region and a second region having a polarization direction different from that of the first region, and the first region and the second region are positioned at least in the intersection region, the intersection region includes a polarization change region where the first region and the second region are alternately arranged in the electrode finger orthogonal direction, in plan view, the first region positioned in the polarization change region overlaps at least the first electrode finger of the first electrode finger and the second electrode finger, and the first region overlaps at least a portion of the first electrode finger, in plan view, the second region positioned in the polarization change region overlaps at least a portion of the second electrode finger, and when a region between centers of one pair of the first electrode finger and the second electrode finger in the electrode finger orthogonal direction is defined as one section, in the polarization change region, the sections in which both of the first region and the second region are positioned are provided periodically.

According to example embodiments of the present invention, it is possible to provide acoustic wave devices that each excite the second harmonic wave and suppress the fundamental wave.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a schematic elevational cross-sectional view illustrating a portion of an acoustic wave device according to a first example embodiment of the present invention.

FIG. 2 is a schematic plan view of the acoustic wave device according to the first example embodiment of the present invention.

FIG. 3 is a schematic plan view of a piezoelectric layer, illustrating a disposition of a first region and a second region according to the first example embodiment of the present invention.

FIG. 4 is a diagram illustrating admittance frequency characteristics according to the first example embodiment of the present invention.

FIG. 5 is a schematic elevational cross-sectional view illustrating a vicinity of two pairs of electrode fingers according to a comparative example, and is a view for describing that a fundamental wave is excited in the comparative example.

FIG. 6 is a schematic elevational cross-sectional view illustrating a vicinity of two pairs of electrode fingers of the acoustic wave device according to the first example embodiment of the present invention, and is a view for describing that a fundamental wave is difficult to be excited in the first example embodiment of the present invention.

FIG. 7 is a schematic elevational cross-sectional view illustrating a vicinity of two pairs of electrode fingers of an acoustic wave device according to the first example embodiment of the present invention, and is a view for describing that a second harmonic wave is excited in the first example embodiment of the present invention.

FIG. 8 is a schematic elevational cross-sectional view illustrating a vicinity of two pairs of electrode fingers of an acoustic wave device according to a first modification example of the first example embodiment of the present invention.

FIG. 9 is a schematic elevational cross-sectional view illustrating a vicinity of two pairs of electrode fingers of an acoustic wave device according to a second modification example of the first example embodiment of the present invention.

FIG. 10 is a schematic elevational cross-sectional view illustrating a vicinity of two pairs of electrode fingers of an acoustic wave device according to a third modification example of the first example embodiment of the present invention.

FIG. 11 is a schematic elevational cross-sectional view illustrating a vicinity of two pairs of electrode fingers of an acoustic wave device according to a second example embodiment of the present invention.

FIG. 12 is a schematic elevational cross-sectional view illustrating a vicinity of two pairs of electrode fingers of an acoustic wave device according to a third example embodiment of the present invention.

FIG. 13 is a schematic elevational cross-sectional view illustrating a vicinity of two pairs of electrode fingers of an acoustic wave device according to a fourth example embodiment of the present invention.

FIG. 14 is a schematic elevational cross-sectional view illustrating a vicinity of two pairs of electrode fingers of an acoustic wave device according to a fifth example embodiment of the present invention.

FIG. 15 is a schematic elevational cross-sectional view illustrating a vicinity of two pairs of electrode fingers of an acoustic wave device according to a first modification example of the fifth example embodiment of the present invention.

FIG. 16 is a schematic elevational cross-sectional view illustrating a vicinity of two pairs of electrode fingers of an acoustic wave device according to a second modification example of the fifth example embodiment of the present invention.

FIG. 17 is a schematic elevational cross-sectional view illustrating a vicinity of two pairs of electrode fingers of an acoustic wave device according to a third modification example of the fifth example embodiment of the present invention.

### DETAILED DESCRIPTION OF THE EXAMPLE EMBODIMENTS

Hereinafter, the present invention will be elucidated by describing specific example embodiments of the present invention with reference to the accompanying drawings.

It should be pointed out that each example embodiment described in the present specification is an example, and partial replacement or combination of configurations is possible between different example embodiments.

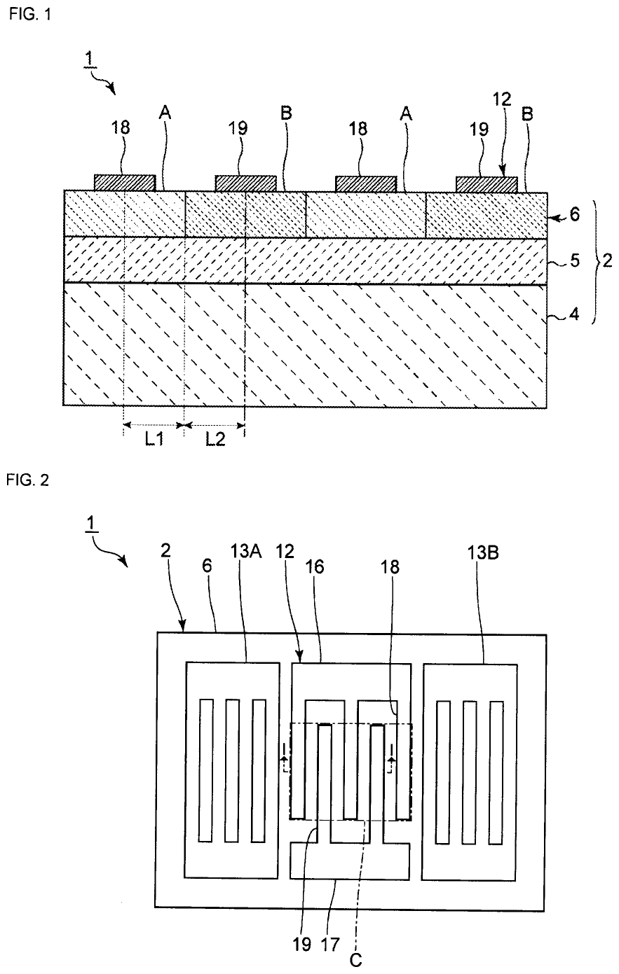

FIG. 1 is a schematic elevational cross-sectional view illustrating a portion of an acoustic wave device according to a first example embodiment of the present invention. FIG. 2 is a schematic plan view of the acoustic wave device according to the first example embodiment. FIG. 1 is a schematic cross-sectional view taken along the line I-I in FIG. 2.

As illustrated in FIG. 1, an acoustic wave device 1 includes a piezoelectric substrate 2. The piezoelectric substrate 2 is a substrate having piezoelectricity. The piezoelectric substrate 2 includes a piezoelectric layer 6 made of a piezoelectric material. More specifically, in the present example embodiment, the piezoelectric substrate 2 includes a high acoustic velocity support substrate 4 as a high acoustic velocity layer, a silicon oxide film 5 as a low acoustic velocity film, and the piezoelectric layer 6. The silicon oxide film 5 is provided on the high acoustic velocity support substrate 4. The piezoelectric layer 6 is provided on the silicon oxide film 5. The laminated configuration of the piezoelectric substrate 2 is not limited to the above. The piezoelectric substrate 2 may include at least the piezoelectric layer 6.

As the material of the piezoelectric layer 6, lithium niobate is used. More specifically, as the material of the piezoelectric layer 6, a rotated Y-cut LiNbO₃ is preferably used. However, the material of the piezoelectric layer 6 is not limited to the above. For example, as the material of the piezoelectric layer 6, lithium tantalate such as LiTaO₃ may be used.

An IDT electrode 12 is provided on the piezoelectric layer 6. An acoustic wave is excited by applying an AC voltage to the IDT electrode 12. The acoustic wave device 1 is configured to be able to use a second harmonic wave. The frequency of the second harmonic wave is approximately twice the frequency of the fundamental wave. The wavelength of the second harmonic wave is approximately ½ of the wavelength of the fundamental wave. When the second harmonic wave is used for the operation of the acoustic wave device 1, the fundamental wave becomes an unnecessary wave.

The high acoustic velocity layer, which is the high acoustic velocity support substrate 4, is a relatively high acoustic velocity layer. More specifically, the acoustic velocity of the bulk wave propagating through the high acoustic velocity layer is higher than the acoustic velocity of the acoustic wave propagating through the piezoelectric layer 6. The high acoustic velocity support substrate 4 as a high acoustic velocity layer in the present example embodiment is a silicon substrate. However, the material of the high acoustic velocity layer is not limited to silicon. In addition, the high acoustic velocity layer may be a high acoustic velocity film. In this case, the piezoelectric substrate 2 may have, for example, a support substrate. A high acoustic velocity film may be provided on the support substrate.

The low acoustic velocity film is a film having a relatively low acoustic velocity. More specifically, the acoustic velocity of the bulk wave propagating through the low acoustic velocity film is lower than the acoustic velocity of the bulk wave propagating through the piezoelectric layer 6. The low acoustic velocity film in the present example embodiment is the silicon oxide film 5. However, the material of the low acoustic velocity film is not limited to silicon oxide.

As illustrated in FIG. 2, the IDT electrode 12 includes a pair of busbars and a plurality of electrode fingers. The pair of busbars are specifically a first busbar 16 and a second busbar 17. The first busbar 16 and the second busbar 17 face each other. The plurality of electrode fingers are specifically a plurality of first electrode fingers 18 and a plurality of second electrode fingers 19. One ends of the plurality of first electrode fingers 18 are respectively coupled to the first busbar 16. One ends of the plurality of second electrode fingers 19 are respectively coupled to the second busbar 17. The plurality of first electrode fingers 18 and the plurality of second electrode fingers 19 are interdigitated with each other.

The first electrode finger 18 and the second electrode finger 19 are coupled to potentials different from each other. For example, one of the first electrode finger 18 and the second electrode finger 19 may be coupled to the signal potential, and the other one may be coupled to the ground potential.

Alternatively, one of the first electrode finger 18 and the second electrode finger 19 may be coupled to the input potential of the signal potential, and the other one may be coupled to the output potential of the signal potential.

A pair of reflectors 13A and 13B are provided on the piezoelectric layer 6. More specifically, the reflector 13A and the reflector 13B are provided to face each other with the IDT electrode 12 interposed therebetween in the acoustic wave propagation direction. The acoustic wave device 1 is a surface acoustic wave resonator.

In the present example embodiment, the IDT electrode 12 and each reflector include a single layer metal film. Specifically, Al is used as a material of the IDT electrode 12 and each reflector. However, the materials of the IDT electrode 12 and each reflector are not limited to the above. Alternatively, the IDT electrode 12 and each reflector may be made of a laminated metal film.

Hereinafter, a direction in which the plurality of first electrode fingers 18 and the plurality of second electrode fingers 19 extend is defined as an electrode finger extending direction, and a direction orthogonal to the electrode finger extending direction is defined as an electrode finger orthogonal direction. The electrode finger orthogonal direction and the acoustic wave propagation direction are parallel to each other. When the IDT electrode 12 is viewed in the electrode finger orthogonal direction, a region where the first electrode finger 18 and the second electrode finger 19, which are adjacent to each other, overlap each other is an intersection region C. The intersection region C is a region of the piezoelectric layer 6 defined by the configuration of the IDT electrode 12. That is, the portion of the piezoelectric layer 6 where the IDT electrode 12 is provided includes the intersection region C.

As illustrated in FIG. 1, the piezoelectric layer 6 includes a first region A and a second region B. The first region A and the second region B are in a relationship in which the polarization directions are inverted from each other. In the present specification, the relationship in which the polarization directions are inverted from each other at two portions means that the acoustic properties of the crystal are the same at the two portions, and only the polarization directions are different from each other by approximately 180°. The difference in the polarization direction between the first region A and the second region B can be evaluated by using, for example, a scanning nonlinear dielectric constant microscope (SNDM) or the like.

The fact that the crystals have the same acoustic properties means that the crystal structures are substantially the same. Whether or not the crystal structures are the same can be determined, for example, by confirming the crystal structure by X-ray diffraction (XRD) or by confirming the polarization state by a nonlinear dielectric constant microscope.

The relationship in which the polarization directions are completely inverted from each other at the two portions is equivalent to the fact that the absolute value of the difference of θ in the Euler angles (ϕ, θ, ψ) of the two portions is 1800. In the first region A and the second region B in the acoustic wave device 1, the angle defined by both of the polarization axes is within about 180°±5°, for example.

In the present example embodiment, the Euler angles are (0°, 110°, 0°) in the first region A. In the second region B, the polarization direction is completely inverted with respect to the first region A. Therefore, in the second region B, the Euler angles are equivalently (0°, 290°, 0°). The polarization directions may be different from each other in the first region A and the second region B.

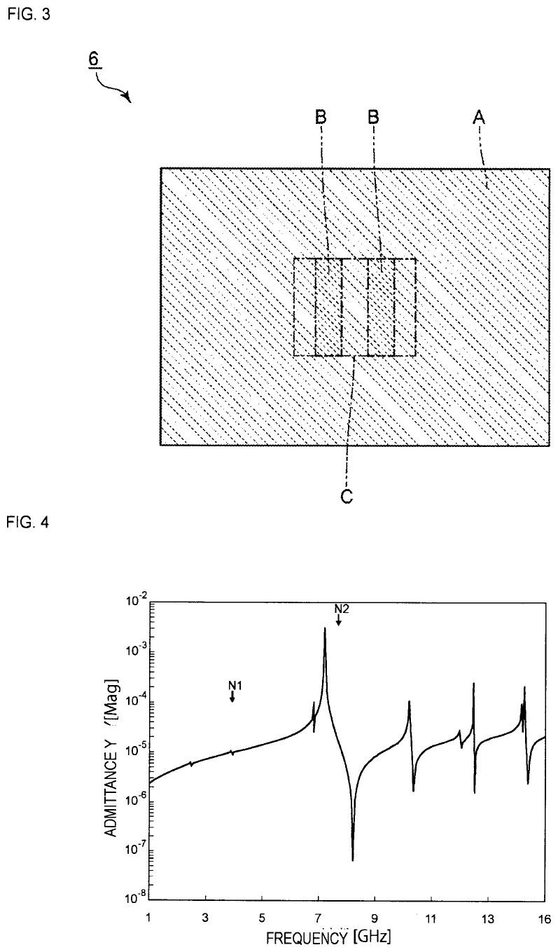

FIG. 3 is a schematic plan view of the piezoelectric layer, illustrating the disposition of the first region and the second region according to the first example embodiment. In FIG. 3, the first region A and the second region B are illustrated by hatching.

The first region A and the second region B are positioned at least in the intersection region C. Specifically, in the present example embodiment, the first region A is also positioned entirely outside the intersection region C. On the other hand, the second region B is positioned only in the intersection region C. That is, the second region B is surrounded by the first region A. However, the second region B may have a portion positioned at the outer side portion of the intersection region C.

Returning to FIG. 1, the first region A and the second region B are respectively positioned in the entirety of the piezoelectric layer 6 in the thickness direction. The first region A or the second region B may be positioned at a portion of the piezoelectric layer 6 in the thickness direction. The first region A and the second region B may be positioned at least on the main surface where the IDT electrode 12 is provided, in the piezoelectric layer 6. [COA 6] The intersection region C includes a polarization change region. Specifically, the polarization change region is a region where the first region A and the second region B are alternately arranged in the electrode finger orthogonal direction. In the present example embodiment, the polarization change region is positioned in the entire intersection region C. However, the polarization change region may be positioned at a portion of the intersection region C in at least one of the electrode finger extending direction and the electrode finger orthogonal direction.

As described above, the first region A according to the present example embodiment illustrated in FIG. 3 includes a plurality of portions positioned in the intersection region C and a portion positioned outside the intersection region C. The plurality of portions of the first region A positioned within the intersection region C are coupled by portions positioned outside the intersection region C. Therefore, the first region A is one continuous region. However, in the present specification, each of the portions of the first region A, which faces each other, with the second region B interposed therebetween may be described as separate first regions A for convenience. As an actual configuration, the piezoelectric layer 6 may include the plurality of first regions A and the plurality of second regions B.

In the present example embodiment, one first region A and one first electrode finger 18 overlap each other in plan view. In the present specification, a plan view means that an acoustic wave device is viewed in a direction corresponding to the upper side in FIG. 1. In FIG. 1, for example, on the high acoustic velocity support substrate 4 side and the piezoelectric layer 6 side, the piezoelectric layer 6 side is the upper side.

In the intersection region C, each first region A overlaps the entirety of one first electrode finger 18 in plan view. Further, each of the first regions A also overlaps the outer side portion of the first electrode finger 18 in the electrode finger orthogonal direction in plan view. However, the first region A may overlap at least a portion of the portion of the first electrode finger 18 positioned in the intersection region C in plan view.

The first region A positioned in the polarization change region does not overlap the second electrode finger 19 in plan view. In an example embodiment of the present invention, the first region A positioned in the polarization change region may overlap at least the first electrode finger 18 of the first electrode finger 18 and the second electrode finger 19 in plan view. The first region A positioned in the polarization change region may overlap the second electrode finger 19 in plan view.

As illustrated in FIG. 1, one second region B and one second electrode finger 19 overlap each other in plan view. More specifically, in the intersection region C, each second region B overlaps the entirety of one second electrode finger 19 in plan view. Further, each of the second regions B also overlaps the outer side portion of the second electrode finger 19 in the electrode finger orthogonal direction in plan view. However, the second region B may overlap at least a portion of the portion of the second electrode finger 19 positioned in the intersection region C in plan view. The second region B does not overlap the first electrode finger 18 in plan view.

In the polarization change region, all of the second electrode fingers 19 overlap the second region B in plan view. In addition, in an example embodiment of the present invention, the second regions B may be periodically provided in the polarization change region. For example, the second region B positioned in the polarization change region may overlap the second electrode finger 19 at one or two intervals in a plan view. The second electrode finger 19 that does not overlap the second region B in plan view may overlap the first region A in plan view.

The boundary between the first region A and the second region B is positioned at a portion of the piezoelectric layer 6 that overlaps the portion between the first electrode finger 18 and the second electrode finger 19 in plan view.

Here, a region between the centers of the pair of first electrode fingers 18 and the second electrode fingers 19 in the electrode finger orthogonal direction is defined as one section. A feature of the present example embodiment is that in the intersection region C, a polarization change region is configured by the first region A and the second region B, and in the polarization change region, the sections in which both of the first region A and the second region B are positioned are provided periodically. Accordingly, the second harmonic wave can be excited and the fundamental wave can be suppressed. Therefore, the second harmonic wave can be preferably used for the operation of the acoustic wave device 1, and the fundamental wave as an unnecessary wave can be suppressed. This will be described below.

The admittance frequency characteristics of the acoustic wave device 1 having the configuration of the first example embodiment are derived by a finite element method (FEM) simulation. The design parameters of the acoustic wave device 1 are as follows. Here, a wavelength defined by the electrode finger pitch of the IDT electrode 12 is defined as A. The electrode finger pitch is the center-to-center distance of the first electrode finger 18 and the second electrode finger 19, which are adjacent to each other, in the electrode finger orthogonal direction. For example, when the electrode finger pitch is defined as p, λ=2p. The wavelength λ is the wavelength of the fundamental wave.

High acoustic velocity support substrate: Material . . . virtual high acoustic velocity material

Silicon oxide film: Material . . . SiO₂, Thickness . . . 0.14λ

Piezoelectric layer: Material . . . rotated Y-cut material LiNbO₃, thickness . . . 0.14λ, Euler angles in first region . . . (0, 110°, 0°), Euler angles in second region . . . (0°, 290°, 0°)

IDT electrode: Material . . . Al, thickness 0.05λ

Wavelength λ . . . 1 μm

Duty ratio . . . 0.3

FIG. 4 is a diagram illustrating admittance frequency characteristics according to the first example embodiment.

An arrow N1 in FIG. 4 indicates the frequency at which the fundamental wave is generated. More specifically, in the present example embodiment, the acoustic velocity of the acoustic wave propagating through the piezoelectric layer 6 is approximately 4000 m/s. From the above design parameters, the wavelength of the fundamental wave is 1 μm. When the wavelength of any wave is defined as λn, the frequency is defined as f, and the acoustic velocity is defined as v, f=v/λn. From the expression, the frequency of the fundamental wave in the present example embodiment is approximately 4 GHz.

An arrow N2 in FIG. 4 indicates a frequency at which a second harmonic wave is generated. The frequency of the second harmonic wave is a frequency exceeding 7 GHz. As illustrated in FIG. 4, in the present example embodiment, the second harmonic wave can be emphatically excited, and the fundamental wave can be effectively suppressed. Therefore, the second harmonic wave can be preferably used for the operation of the acoustic wave device 1, and the fundamental wave as an unnecessary wave can be effectively suppressed.

The reason why the above effect in the first example embodiment can be obtained will be described below. In addition, a comparative example is also illustrated for reference. The comparative example is different from the first example embodiment in a fact that the piezoelectric layer does not include a region of which the polarization direction is inverted. In the comparative example, the polarization direction of the piezoelectric layer is constant.

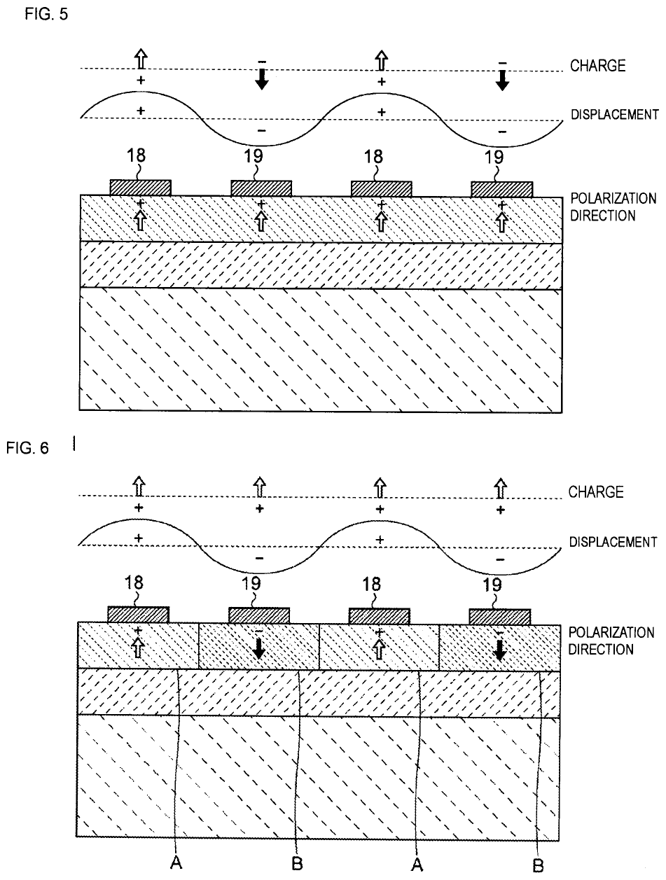

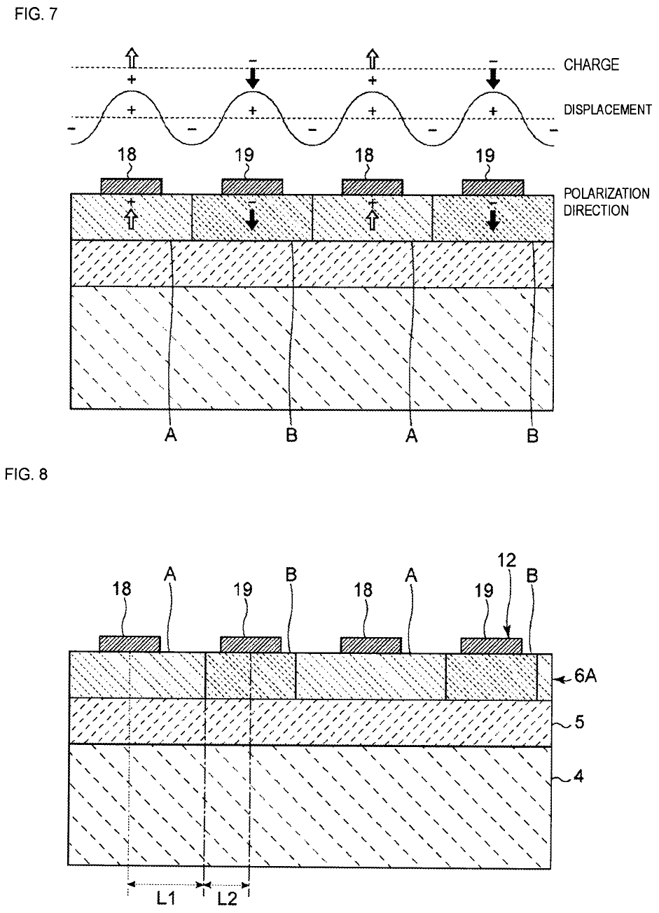

FIG. 5 is a schematic elevational cross-sectional view illustrating a vicinity of two pairs of electrode fingers according to a comparative example, and is a view for describing that a fundamental wave is excited in the comparative example. FIG. 6 is a schematic elevational cross-sectional view illustrating a vicinity of two pairs of electrode fingers of the acoustic wave device according to the first example embodiment, and is a view for describing that the fundamental wave is difficult to be excited in the first example embodiment. FIG. 7 is a schematic elevational cross-sectional view illustrating a vicinity of two pairs of electrode fingers of the acoustic wave device according to the first example embodiment, and is a view for describing that a second harmonic wave is excited in the first example embodiment.

In FIGS. 5 to 7, the polarization direction in the piezoelectric layer is schematically illustrated. In FIGS. 5 to 7, as the sign of the polarization direction, the sign of the main surface side where each electrode finger is provided of the piezoelectric layer is illustrated. In FIGS. 5 and 6, a displacement and the accompanying charge when it is assumed that the fundamental wave is excited are schematically illustrated. In FIG. 7, a displacement and the accompanying charge when it is assumed that the second harmonic wave is excited are schematically illustrated.

As illustrated in FIG. 5, the sign of the charge generated by the displacement of the piezoelectric layer can be represented by the product of the sign of the polarization direction of the piezoelectric layer and the direction of the displacement. In the comparative example, the sign of the polarization direction is positive, and the sign of the direction of the displacement is positive at the portion where the first electrode finger 18 is provided. Therefore, the sign of the charge generated at the portion where the first electrode finger 18 is provided is positive. The sign of the polarization direction is also positive at the portion where the second electrode finger 19 is provided. At the portion where the second electrode finger 19 is provided, the displacement direction is negative. Therefore, the sign of the charge generated at the portion where the second electrode finger 19 is provided is negative.

As described above, the charge generated at the portion where the first electrode finger 18 is provided and the charge generated at the portion where the second electrode finger 19 is provided have different signs from each other. Therefore, the first electrode finger 18 and the second electrode finger 19 have a potential difference. That is, the excitation of the fundamental wave matches the fact that the first electrode finger 18 and the second electrode finger 19 have the potential difference. Therefore, in the comparative example, the fundamental wave is emphatically excited.

On the other hand, as illustrated in FIG. 6, in a first example embodiment, the first region A and the second region B are in a relationship in which the polarization directions are inverted from each other. Accordingly, the portion where the first electrode finger 18 is provided and the portion where the second electrode finger 19 is provided are in a relationship in which the polarization directions are inverted from each other. As a result, when it is assumed that the fundamental wave is excited, the signs of the charges generated in the first electrode finger 18 and the second electrode finger 19 are the same. Therefore, the first electrode finger 18 and the second electrode finger 19 do not have a potential difference. That is, there is a portion where the fundamental wave is excited and the portion where the first electrode finger 18 and the second electrode finger 19 have the potential difference do not match. Therefore, in the first example embodiment, the excitation of the fundamental wave can be effectively suppressed.

Further, FIG. 6 illustrates an ideal state. FIG. 6 illustrates that the fundamental wave is not excited. However, the first region A and the second region B need not be in a relationship in which the polarization directions are inverted from each other. In the first region A and the second region B, the polarization directions may be different from each other. In this case, the potential difference between the first electrode finger 18 and the second electrode finger 19 due to the excitation of the fundamental wave is reduced. Therefore, the intensity of the response due to the fundamental wave can be reduced. That is, the fundamental wave can be suppressed.

As illustrated in FIG. 7, when it is assumed that the second harmonic wave is excited, the directions of displacement are the same at the portion where the first electrode finger 18 is provided and at the portion where the second electrode finger 19 is provided. In addition, the portion where the first electrode finger 18 is provided and the portion where the second electrode finger 19 is provided are in a relationship in which the polarization directions are inverted from each other. Accordingly, the charge generated at the portion where the first electrode finger 18 is provided and the charge generated at the portion where the second electrode finger 19 is provided have different signs from each other. Therefore, the first electrode finger 18 and the second electrode finger 19 have a potential difference. That is, the excitation of the second harmonic wave matches the fact that the first electrode finger 18 and the second electrode finger 19 have the potential difference. Therefore, in the first example embodiment, the second harmonic wave is emphatically excited.

When the piezoelectric layer 6 having the first region A and the second region B is obtained, for example, film formation processing may be performed on the wafer corresponding to the piezoelectric layer having only the first region A. As a result, the piezoelectric layer 6 having the first region A and the second region B may be formed. In this case, for example, the crystallinity at a portion of the surface of the wafer may be disturbed in advance by surface treatment such as ion beam irradiation or plasma treatment. Alternatively, the surface diffusion may be reduced by lowering a film formation temperature when performing film formation processing on the wafer. Through these, the film having the second region B can be grown. For example, by forming a resist pattern during the surface treatment, the disposition of the first region A and the second region B can be adjusted.

Alternatively, when film formation is performed by sputtering, a milling effect due to self-bias may be used. Accordingly, the preferential orientation surface can be controlled, and the polarization direction of the second region B can be easily inclined with respect to the polarization direction of the first region A. More specifically, for example, when LiNbO₃ is used as the wafer material, ion beam irradiation may be performed from a normal direction of the main surface of the wafer. Accordingly, a film in which the crystal c axis direction is inclined from the normal direction can be easily grown. As a result, a film having an inclined polarization direction can be formed.

After the second region B is formed in the wafer, the second region B may be positioned on the entirety of the wafer in the thickness direction, by adjusting the thickness of the wafer or the like. After that, the plurality of piezoelectric layers 6 may be obtained by dividing the wafer.

Hereinafter, a preferable configuration of the first example embodiment will be described.

As illustrated in FIG. 1, it is preferable that both of the first region A and the second region B are positioned in all the sections in the polarization change region. Accordingly, the second harmonic wave can be more reliably and emphatically excited, and the fundamental wave can be more reliably and effectively suppressed.

It is preferable that the angle defined by the polarization axis in the first region A and the polarization axis in the second region B is within a range of about 180°±5°, for example. In this case, as described above, the first region A and the second region B are in a relationship in which the polarization directions are inverted from each other. Accordingly, the second harmonic wave can be emphatically excited, and the fundamental wave can be effectively suppressed.

As illustrated in FIG. 1, in one section in the polarization change region, when a dimension along the electrode finger orthogonal direction of the first region A is defined as L1, and a dimension along the electrode finger orthogonal direction of the second region B is defined as L2, L2/L1 is preferably within a range of about 1±0.1, for example. In this case, the difference between the dimension L1 and the dimension L2 is sufficiently small. Accordingly, the second harmonic wave can be more reliably and emphatically excited, and the fundamental wave can be more reliably and effectively suppressed.

It is preferable that the piezoelectric substrate 2 is a laminated substrate including the high acoustic velocity layer and the piezoelectric layer 6. It is more preferable that the piezoelectric substrate 2 is a laminated substrate in which the high acoustic velocity layer, the low acoustic velocity film, and the piezoelectric layer 6 are laminated in this order. In the first example embodiment, the high acoustic velocity layer is the high acoustic velocity support substrate 4, and the low acoustic velocity film is the silicon oxide film 5.

Since the frequency of the second harmonic wave is high, there is a concern that the energy of the second harmonic wave need not be sufficiently confined on the piezoelectric layer 6 side. On the other hand, when the piezoelectric substrate 2 has a laminated configuration as described above, the energy of the second harmonic wave can be effectively confined on the piezoelectric layer 6 side.

It is preferable that the low acoustic velocity film is the silicon oxide film 5, as in the first example embodiment. As a result, the absolute value of the temperature coefficient of frequency (TCF) of the acoustic wave device 1 can be reduced. Accordingly, the frequency temperature characteristics of the acoustic wave device 1 can be improved.

However, as the material of the low acoustic velocity film, for example, glass, silicon oxide, silicon oxynitride, lithium oxide, tantalum oxide, or a dielectric such as a compound obtained by adding fluorine, carbon, or boron to silicon oxide, or a material of which the main components are above materials can also be used.

In the present specification, the main component means a component that accounts for more than 50% by weight. The material of the main component may exist in any one state of single crystal, polycrystal, and amorphous, or a mixed state thereof.

In the present example embodiment, the piezoelectric layer 6 is provided directly on the silicon oxide film 5 as the low acoustic velocity film. The piezoelectric layer 6 may be indirectly provided on the low acoustic velocity film with a piezoelectric layer other than the piezoelectric layer 6, a dielectric layer interposed therebetween, or the like.

As a material of the high acoustic velocity support substrate 4 which is a high acoustic velocity layer, silicon is used. However, the material of the high acoustic velocity layer is not limited to the above. Examples of materials for the high acoustic velocity layer include piezoelectric materials such as aluminum nitride, lithium tantalate, lithium niobate, and quartz crystal, ceramics such as alumina, sapphire, magnesia, silicon nitride, silicon carbide, zirconia, cordierite, mullite, steatite, forsterite, spinel, or sialon, dielectrics such as aluminum oxide, silicon oxynitride, diamond-like carbon (DLC), or diamond, semiconductors such as silicon, and materials of which main components are the above materials. The spinel includes an aluminum compound containing one or more elements selected from Mg, Fe, Zn, Mn, and the like, and oxygen. Examples of the spinel include MgAl₂O₄, FeAl₂O₄, ZnAl₂O₄, and MnAl₂O₄.

In the first example embodiment, the piezoelectric layer 6 is indirectly provided on the high acoustic velocity support substrate 4 as a high acoustic velocity layer, with the low acoustic velocity film interposed therebetween. For example, the piezoelectric layer 6 may be indirectly provided on the high acoustic velocity layer with a piezoelectric layer other than the piezoelectric layer 6 or a dielectric film other than the low acoustic velocity film interposed therebetween. Alternatively, the piezoelectric layer 6 may be provided directly on the high acoustic velocity layer.

As illustrated in FIG. 1, in the acoustic wave device 1, the boundary between the first region A and the second region B is positioned at the center in the electrode finger orthogonal direction in each section. The boundary extends in the normal direction of the main surface of the piezoelectric layer 6. That is, L2/L1=1 in the acoustic wave device 1. In addition, the disposition of the boundary between the first region A and the second region B is not limited to the above. Hereinafter, first to third modification examples of the first example embodiment that are different from the first example embodiment only in the disposition of the boundary between the first region A and the second region B will be described. In the first to third modification examples, similarly to the first example embodiment, the second harmonic wave can be excited and the fundamental wave can be suppressed.

In the piezoelectric layer 6A of the first modification example illustrated in FIG. 8, L2/L1<1. In the present modification example, similarly to the first example embodiment, the boundary between the first region A and the second region B extends in the normal direction of the main surface of the piezoelectric layer 6A. The center of the first region A in the electrode finger orthogonal direction and the center of the first electrode finger 18 in the electrode finger orthogonal direction overlap each other in plan view. The center of the second region B in the electrode finger orthogonal direction and the center of the second electrode finger 19 in the electrode finger orthogonal direction overlap each other in plan view.

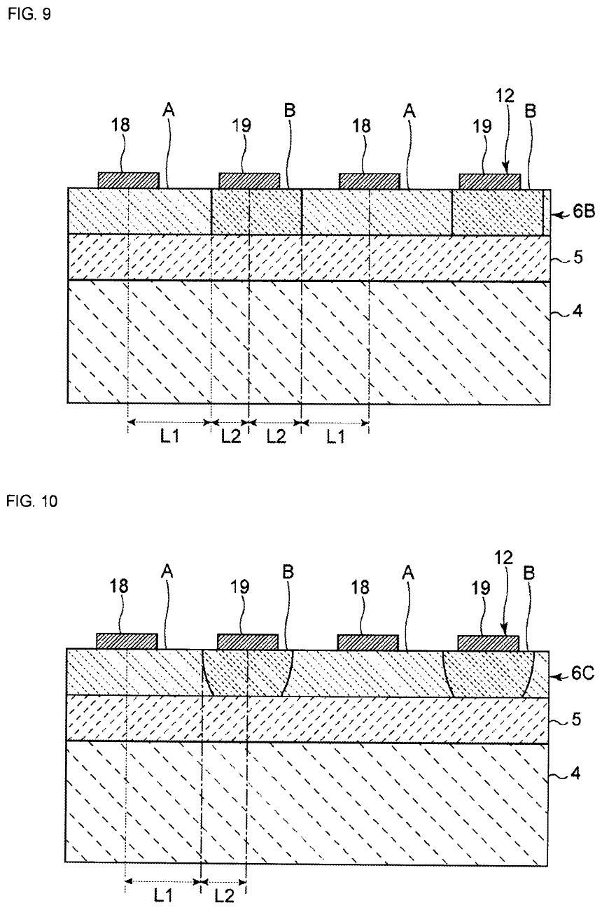

In a piezoelectric layer 6B of the second modification example illustrated in FIG. 9, the center of the first region A in the electrode finger orthogonal direction and the center of the first electrode finger 18 in the electrode finger orthogonal direction do not overlap each other in plan view. The center of the second region B in the electrode finger orthogonal direction and the center of the second electrode finger 19 in the electrode finger orthogonal direction do not overlap each other in plan view. Therefore, the dimension L1 in adjacent sections is different from each other. In the present modification example, similarly to the first modification example, the boundary between the first region A and the second region B extends in the normal direction of the main surface of the piezoelectric layer 6B. Similarly, the dimension L2 in adjacent sections is different from each other. However, in the present modification example, L2/L1<1 is satisfied in any section.

In a piezoelectric layer 6C of the third modification example illustrated in FIG. 10, the boundary between the first region A and the second region B has a curved shape in the cross section along the electrode finger orthogonal direction. More specifically, the dimension L2 of the second region B decreases as the distance from the second electrode finger 19 increases in the thickness direction of the piezoelectric layer 6C. In FIG. 10, the dimension L1 and the dimension L2 on the main surface where the IDT electrode 12 is provided, in the piezoelectric layer 6C. In the present modification example, L2/L1<1 is satisfied at any position in the thickness direction of the piezoelectric layer 6C.

The configuration of the boundaries between the first region A and the second region B in the first to third modification examples can be used in other aspects of example embodiments of the present invention.

As schematically illustrated in FIG. 3, the piezoelectric layer 6 includes one first region A and a plurality of second regions B. However, the piezoelectric layer 6 may include a plurality of first regions A and a plurality of second regions B. For example, some second regions B may surround one first region A in the plurality of first regions A. In this case, specifically, for example, some second regions B include a plurality of portions positioned in the intersection region C and a plurality of portions positioned outside the intersection region C. In addition, the plurality of portions of the second region B positioned within the intersection region C are coupled by portions positioned outside the intersection region C. One first region A is surrounded by the second region B.

Incidentally, a dielectric film may be provided on the piezoelectric layer 6 illustrated in FIG. 1. Accordingly, since the IDT electrode 12 is protected by the dielectric film, the IDT electrode 12 is less likely to be damaged. As the material of the dielectric film, for example, silicon oxide, silicon nitride, silicon oxynitride, or the like can be used. A configuration in which the dielectric film is provided can be used in other aspects of example embodiments of the present invention.

A piezoelectric layer other than the piezoelectric layer 6 or a dielectric layer may be provided between the piezoelectric layer 6 and the IDT electrode 12. In this case, the specific bandwidth of the acoustic wave device can be adjusted by adjusting the thickness of the piezoelectric layer or the dielectric layer, or the like. A configuration in which the piezoelectric layer or the dielectric layer is provided can be used in other aspects of example embodiments of the present invention.

In the first example embodiment, the electrode finger pitch of the IDT electrode 12 is constant. In an example embodiment of the present invention, the IDT electrode 12 may include a plurality of portions having different electrode finger pitches. For example, in the IDT electrode 12, the electrode finger pitch may be random. In this case, L2/L1 is preferably a value based on a ratio of the center-to-center distance of the adjacent first electrode fingers 18 in the electrode finger orthogonal direction and the center-to-center distance of adjacent second electrode fingers 19 in the electrode finger orthogonal direction. Specifically, when the center-to-center distance of adjacent first electrode fingers 18 in the electrode finger orthogonal direction is defined as p1 and the center-to-center distance of adjacent second electrode fingers 19 in the electrode finger orthogonal direction is defined as p2, (p2/p1)/(L2/L1) is preferably in a range within about 1±0.1, for example. Accordingly, the second harmonic wave can be emphatically excited and the fundamental wave can be suppressed.

The width of the electrode fingers of the IDT electrode 12 in the first example embodiment is constant. The width of the electrode finger is a dimension of the electrode finger along an electrode finger orthogonal direction. However, in an example embodiment of the present invention, the plurality of electrode fingers of the IDT electrode 12 may include electrode fingers having different widths.

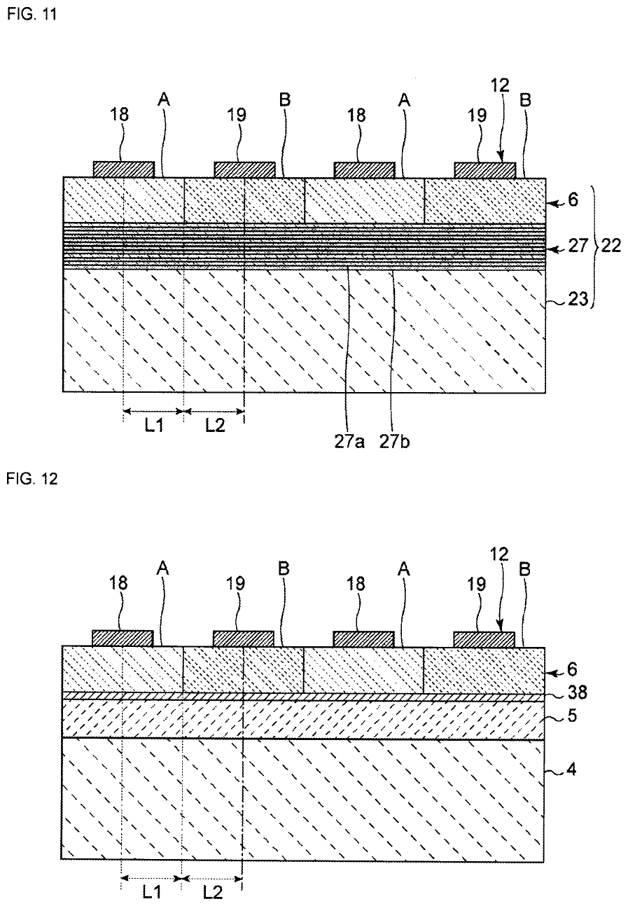

FIG. 11 is a schematic elevational cross-sectional view illustrating a vicinity of two pairs of electrode fingers of an acoustic wave device according to the second example embodiment.

The present example embodiment is different from the first example embodiment in a laminated configuration of a piezoelectric substrate 22. The acoustic wave device of the present example embodiment has the same configuration as the acoustic wave device 1 of the first example embodiment in other respects than the above.

The piezoelectric substrate 22 includes a support substrate 23, an acoustic reflection film 27, and a piezoelectric layer 6. The acoustic reflection film 27 is provided on the support substrate 23. The piezoelectric layer 6 is provided on the acoustic reflection film 27.

The support substrate 23 is a silicon substrate. The support substrate 23 in the present example embodiment is a high acoustic velocity support substrate as a high acoustic velocity layer. Therefore, as the material of the support substrate 23, the material of the above-described high acoustic velocity layer other than silicon can also be used. However, the support substrate 23 need not be the high acoustic velocity layer. As the material of the support substrate 23, for example, a material different from the material of the high acoustic velocity layer, such as resin, can be used.

The acoustic reflection film 27 is a multilayer body of a plurality of acoustic impedance layers. Specifically, the acoustic reflection film 27 include a plurality of low acoustic impedance layers 27a and a plurality of high acoustic impedance layers 27b. The low acoustic impedance layer 27a is a layer having a relatively low acoustic impedance. On the other hand, the high acoustic impedance layer 27b is a layer having a relatively high acoustic impedance.

In an acoustic impedance layer, having a relatively low acoustic impedance means that the acoustic impedance layer is lower than that of an acoustic impedance layer adjacent to the acoustic impedance layer. In an acoustic impedance layer, having a relatively high acoustic impedance means that the acoustic impedance layer is higher than that of an acoustic impedance layer adjacent to the acoustic impedance layer. The low acoustic impedance layer 27a and the high acoustic impedance layer 27b are alternately laminated. The low acoustic impedance layer 27a is a layer positioned closest to the piezoelectric layer 6 side in the acoustic reflection film 27.

The acoustic reflection film 27 includes six low acoustic impedance layers 27a and six high acoustic impedance layers 27b, for example. However, the acoustic reflection film 27 may include at least one low acoustic impedance layer 27a and at least one high acoustic impedance layer 27b.

As the material of the low acoustic impedance layer 27a, for example, silicon oxide or aluminum can be used. As the material of the high acoustic impedance layer 27b, for example, a metal such as platinum or tungsten, or a dielectric such as aluminum nitride or silicon nitride can be used.

The piezoelectric layer 6 is configured in the same manner as that of the first example embodiment. Therefore, in the intersection region, a polarization change region is configured by the first region A and the second region B, and both of the first region A and the second region B are positioned in each section in the polarization change region. Accordingly, the second harmonic wave can be excited and the fundamental wave can be suppressed. Therefore, the second harmonic wave can be preferably used for the operation of the acoustic wave device, and the fundamental wave as an unnecessary wave can be suppressed.

In the present example embodiment, the piezoelectric layer 6 is provided directly on the acoustic reflection film 27. However, the piezoelectric layer 6 may be indirectly provided on the acoustic reflection film 27 with a piezoelectric layer other than the piezoelectric layer 6, a dielectric layer interposed therebetween, or the like. The piezoelectric substrate 22 may include a silicon oxide film as the dielectric layer. In the piezoelectric substrate 22, the piezoelectric layer 6 and the acoustic reflection film 27 may be laminated. As a result, the energy of the second harmonic wave can be effectively confined on the piezoelectric layer 6 side.

A silicon oxide film may be provided between the support substrate 23 and the acoustic reflection film 27. In this case, the absolute value of the temperature coefficient of frequency of the acoustic wave device can be reduced. Accordingly, the frequency temperature characteristics of the acoustic wave device can be improved.

FIG. 12 is a schematic elevational cross-sectional view illustrating a vicinity of two pairs of electrode fingers of an acoustic wave device according to the third example embodiment.

The present example embodiment is different from the first example embodiment in a fact that an electrode layer 38 is provided between the silicon oxide film 5 and the piezoelectric layer 6. As a material of the electrode layer 38, an appropriate metal can be used. The acoustic wave device of the present example embodiment has the same configuration as the acoustic wave device 1 of the first example embodiment in other respects than the above.

The piezoelectric layer 6 is configured in the same manner as that of the first example embodiment. Therefore, in the intersection region, a polarization change region is configured by the first region A and the second region B, and both of the first region A and the second region B are positioned in each section in the polarization change region. Accordingly, the second harmonic wave can be excited and the fundamental wave can be suppressed. Therefore, the second harmonic wave can be preferably used for the operation of the acoustic wave device, and the fundamental wave as an unnecessary wave can be suppressed.

The IDT electrode 12 and the electrode layer 38 face each other with the piezoelectric layer 6 interposed therebetween. Accordingly, the electrostatic capacitance can be increased. For example, the magnitude of the electrostatic capacitance can be adjusted by adjusting the thickness of the piezoelectric layer 6. As a result, the specific bandwidth in the acoustic wave device can be adjusted.

In the present example embodiment, the piezoelectric layer 6 is provided directly on the electrode layer 38. However, the piezoelectric layer 6 may be indirectly provided on the electrode layer 38 with a piezoelectric layer other than the piezoelectric layer 6, a dielectric layer interposed therebetween, or the like. In this case, the electrostatic capacitance of the acoustic wave device can be adjusted by adjusting the thickness of the piezoelectric layer or the dielectric layer, or the like. As a result, the specific bandwidth of the acoustic wave device can be adjusted.

For example, instead of the silicon oxide film 5, the acoustic reflection film 27 illustrated in FIG. 11 may be used.

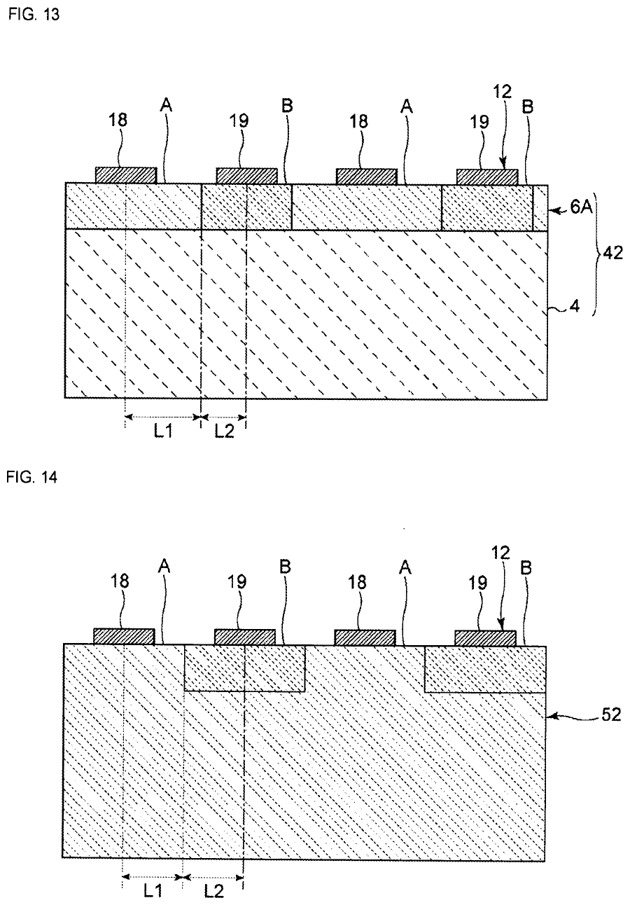

FIG. 13 is a schematic elevational cross-sectional view illustrating a vicinity of two pairs of electrode fingers of an acoustic wave device according to the fourth example embodiment.

The present example embodiment is different from the first example embodiment in a fact that the piezoelectric layer 6A is provided directly on the high acoustic velocity support substrate 4. The present example embodiment is different from the first example embodiment in a fact that L2/L1<1. The piezoelectric layer 6A is configured similarly to that of the first modification example of the first example embodiment illustrated in FIG. 8. The acoustic wave device of the present example embodiment has the same configuration as the acoustic wave device 1 of the first example embodiment in other respects than the above.

In the piezoelectric layer 6A, the disposition of the boundary between the first region A and the second region B is different from that of the piezoelectric layer 6 in the first example embodiment. However, in the intersection region, a polarization change region is configured by the first region A and the second region B, and both of the first region A and the second region B are positioned in each section in the polarization change region. Accordingly, the second harmonic wave can be excited and the fundamental wave can be suppressed. Therefore, the second harmonic wave can be preferably used for the operation of the acoustic wave device, and the fundamental wave as an unnecessary wave can be suppressed.

In the present example embodiment, the high acoustic velocity support substrate 4 and the piezoelectric layer 6A are laminated in the piezoelectric substrate 42. As a result, the energy of the second harmonic wave can be effectively confined on the piezoelectric layer 6A side.

FIG. 14 is a schematic elevational cross-sectional view illustrating a vicinity of two pairs of electrode fingers of an acoustic wave device according to the fifth example embodiment.

The present example embodiment is different from the first example embodiment in a fact that a piezoelectric substrate 52 includes only a piezoelectric layer. The piezoelectric substrate 52 is a substrate made of only a piezoelectric material. The acoustic wave device of the present example embodiment has the same configuration as the acoustic wave device 1 of the first example embodiment in other respects than the above.

On the main surface on which the IDT electrode 12 is provided, in the piezoelectric substrate 52, the disposition of the first region A and the second region B is the same as that in the first example embodiment. However, the second region B is positioned at a portion of the piezoelectric substrate 52 in the thickness direction. The first region A and the second region B are laminated at the portion where the second region B is positioned in plan view.

In the piezoelectric substrate 52, similarly to the first example embodiment, in the intersection region, a polarization change region is configured by the first region A and the second region B, and both of the first region A and the second region B are positioned in each section in the polarization change region. Accordingly, the second harmonic wave can be excited and the fundamental wave can be suppressed. Therefore, the second harmonic wave can be preferably used for the operation of the acoustic wave device, and the fundamental wave as an unnecessary wave can be suppressed.

As illustrated in FIG. 14, at the portion where the second region B is positioned in the thickness direction of the piezoelectric substrate 52, the boundary between the first region A and the second region B extends in the normal direction of the main surface of the piezoelectric substrate 52. At the portion, L2/L1=1.

However, even when the piezoelectric substrate 52 is made of only the piezoelectric layer, the disposition of the boundary between the first region A and the second region B is not limited to the above. Hereinafter, first to third modification examples of the fifth example embodiment that are different from the fifth example embodiment only in the disposition of the boundary between the first region A and the second region B will be described. In the first to third modification examples, similarly to the fifth example embodiment, the second harmonic wave can be excited and the fundamental wave can be suppressed.

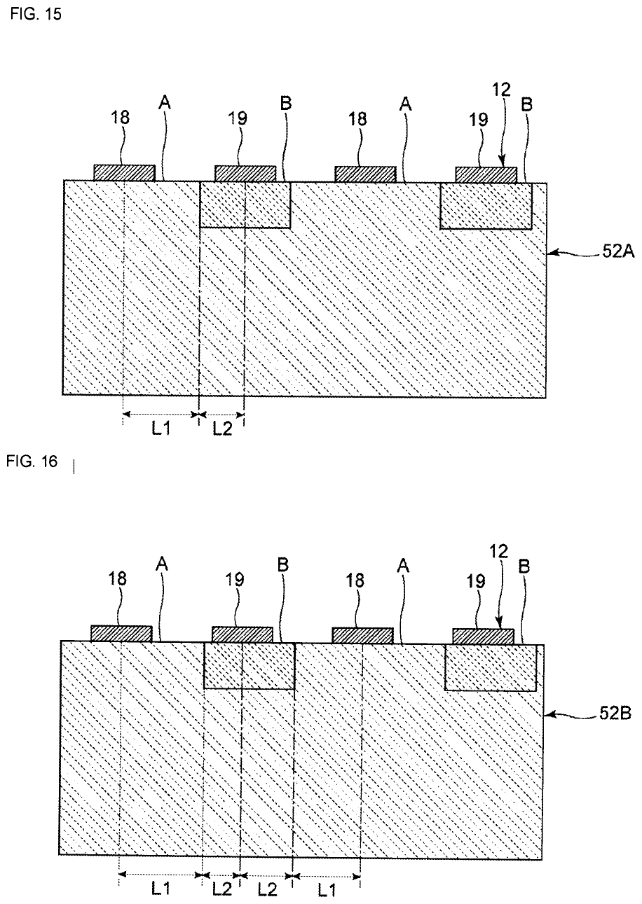

In the piezoelectric substrate 52A of the first modification example illustrated in FIG. 15, L2/L1<1. In the present modification example, similarly to the fifth example embodiment, the boundary between the first region A and the second region B extends in the normal direction of the main surface of the piezoelectric substrate 52A. The center of the first region A in the electrode finger orthogonal direction and the center of the first electrode finger 18 in the electrode finger orthogonal direction overlap each other in plan view. The center of the second region B in the electrode finger orthogonal direction and the center of the second electrode finger 19 in the electrode finger orthogonal direction overlap each other in plan view.

In a piezoelectric substrate 52B of the second modification example illustrated in FIG. 16, the center of the first region A in the electrode finger orthogonal direction and the center of the first electrode finger 18 in the electrode finger orthogonal direction do not overlap each other in plan view. The center of the second region B in the electrode finger orthogonal direction and the center of the second electrode finger 19 in the electrode finger orthogonal direction do not overlap each other in plan view. Therefore, the dimension L1 in adjacent sections is different from each other. Similarly, the dimension L2 in adjacent sections is different from each other. In the present modification example, similarly to the first modification example, the boundary between the first region A and the second region B extends in the normal direction of the main surface of the piezoelectric substrate 52B. In the present modification example, L2/L1<1 is satisfied in any section.

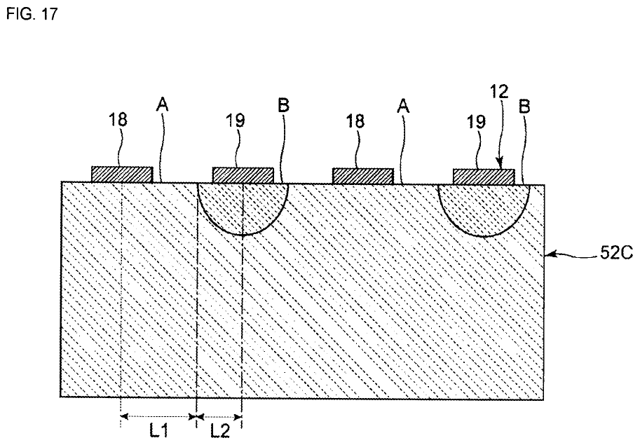

In a piezoelectric substrate 52C of the third modification example illustrated in FIG. 17, the boundary between the first region A and the second region B has a curved shape in the cross section along the electrode finger orthogonal direction. More specifically, the dimension L2 of the second region B decreases as the distance from the second electrode finger 19 increases in the thickness direction of the piezoelectric substrate 52C. In FIG. 17, the dimension L1 and the dimension L2 on the main surface where the IDT electrode 12 is provided, in the piezoelectric substrate 52C. In the present modification example, L2/L1<1 at any position in the thickness direction of the piezoelectric substrate 52C.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An acoustic wave device comprising:
a piezoelectric substrate including a piezoelectric layer; and
an IDT electrode provided on the piezoelectric layer, and including a plurality of first electrode fingers and a plurality of second electrode fingers that are interdigitated with each other and coupled to mutually different potentials; wherein
a portion of the piezoelectric layer where the IDT electrode is provided includes an intersection region, and when a direction in which the plurality of first electrode fingers and the plurality of second electrode fingers extend is defined as an electrode finger extending direction, a direction orthogonal to the electrode finger extending direction is defined as an electrode finger orthogonal direction, and the IDT electrode is viewed in the electrode finger orthogonal direction, a region where the first electrode finger and the second electrode finger, which are adjacent to each other, overlap each other is the intersection region;
the piezoelectric layer includes a first region and a second region having a polarization direction different from that of the first region, and the first region and the second region are positioned at least in the intersection region;
the intersection region includes a polarization change region where the first region and the second region are alternately arranged in the electrode finger orthogonal direction;
in plan view, the first region positioned in the polarization change region overlaps at least the first electrode finger of the first electrode finger and the second electrode finger, and the first region overlaps at least a portion of the first electrode finger;
in plan view, the second region positioned in the polarization change region overlaps at least a portion of the second electrode finger; and
when a region between centers of one pair of the first electrode finger and the second electrode finger in the electrode finger orthogonal direction is defined as one section, in the polarization change region, the sections in which both of the first region and the second region are positioned are provided periodically.

2. The acoustic wave device according to claim 1, wherein both of the first region and the second region are positioned in all of the sections in the polarization change region.

3. The acoustic wave device according to claim 1, wherein in the first region and the second region, the polarization directions are inverted from each other, an angle defined by a polarization axis in the first region and a polarization axis in the second region is within a range of about 180°±5°.

4. The acoustic wave device according to claim 1, wherein in the section in the polarization change region, when a dimension along the electrode finger orthogonal direction of the first region is defined as L1, and a dimension along the electrode finger orthogonal direction of the second region is defined as L2, L2/L1 is within a range of about 1±0.1.

5. The acoustic wave device according to claim 1, wherein
the piezoelectric substrate includes a high acoustic velocity layer;
the piezoelectric layer is provided directly or indirectly on the high acoustic velocity layer; and
an acoustic velocity of a bulk wave that propagates through the high acoustic velocity layer is higher than an acoustic velocity of an acoustic wave that propagates through the piezoelectric layer.

6. The acoustic wave device according to claim 1, wherein
the piezoelectric substrate includes an acoustic reflection film;
the piezoelectric layer is provided directly or indirectly on the acoustic reflection film; and
the acoustic reflection film includes at least one low acoustic impedance layer having a relatively low acoustic impedance and at least one high acoustic impedance layer having a relatively high acoustic impedance, and the low acoustic impedance layer and the high acoustic impedance layer are alternately laminated.

7. The acoustic wave device according to claim 1, wherein
the piezoelectric substrate includes an electrode layer; and
the piezoelectric layer is provided directly or indirectly on the electrode layer.

8. The acoustic wave device according to claim 1, wherein
the piezoelectric substrate includes a silicon oxide film; and
the piezoelectric layer is provided directly or indirectly on the silicon oxide film.

9. The acoustic wave device according to claim 1, wherein the piezoelectric layer includes lithium niobate or lithium tantalate.

10. The acoustic wave device according to claim 1, wherein the acoustic wave device is structured to use a second harmonic wave.

11. The acoustic wave device according to claim 5, wherein the high acoustic velocity layer includes a silicon substrate.

12. The acoustic wave device according to claim 1, further comprising a pair of reflectors at opposite ends of the IDT electrode.

13. The acoustic wave device according to claim 12, wherein the reflectors and the IDT electrode include a single layer metal film or a laminated metal film.

14. The acoustic wave device according to claim 1, wherein the acoustic wave device is a surface acoustic wave resonator.

15. The acoustic wave device according to claim 1, wherein Euler angles are (0°, 110°, 0°) in the first region and Euler angles in the second region are (0°, 290°, 0°).

16. The acoustic wave device according to claim 1, wherein the polarization change region is provided in an entirety of the intersection region.

17. The acoustic wave device according to claim 1, wherein the polarization change region is provided in only a portion of the intersection region.

18. The acoustic wave device according to claim 1, wherein the sections in which both of the first region and the second region are positioned are provided periodically to generate a second harmonic wave.

19. The acoustic wave device according to claim 1, wherein the sections in which both of the first region and the second region are positioned are provided periodically to suppress a fundamental wave.

20. The acoustic wave device according to claim 1, further comprising a dielectric film on the piezoelectric layer.
